(19) United States
(12) Patent Application Publication
(10) Pub. No.: US 2007/0115145 A1
(43) Pub. Date: May 24, 2007

(54) DIRECTION INDICATOR CONTROL DEVICE FOR VEHICLES

(76) Inventor: Matthias Frey, Altensteig (DE)

Correspondence Address: HARNESS, DICKEY & PIERCE, P.L.C., P.O. BOX 828, BLOOMFIELD HILLS, MI, 48303, US

(21) Appl. No.: 11/556,436

(22) Filed: Nov. 3, 2006

Related U.S. Application Data
(63) Continuation of application No. PCT/EP05/04841, filed on May 4, 2005.

(30) Foreign Application Priority Data
May 6, 2004 (DE) 10 2004 022 438.2

(51) Int. Cl. H03K 17/94; H04L 17/02; B60Q 1/26

(52) U.S. Cl. 341/20; 341/173; 340/468

(57) ABSTRACT

The present invention relates to a direction indicator control device for vehicles, particularly trucks, comprising a driving unit (16) for activating a left and/or right direction indicator in response to a driving command, a transmitting unit (12) for transmitting a start command, and a receiving unit (14). The receiving unit (14) comprises a receiver (24) for receiving said start command; a memory (28) storing at least one sequence of driving commands, and a selection and control circuit (30) adapted to select any one of the sequences of driving commands stored in the memory in response to the start command and to transmit the driving commands of the selected sequence to the driving unit as to activate the direction indicators.

### CROSSREFERENCES TO RELATED APPLICATIONS

This application is a continuation of international patent application PCT/EP2005/004841, filed May 4, 2005 designating the U.S., which international patent application has been published in German language and claims priority from German patent application DE 10 2004 022 436, filed on May 6, 2004. The entire contents of these priority applications are incorporated herein by reference.

### BACKGROUND OF THE INVENTION

The present invention relates to a direction indicator control device for vehicles, particularly for trucks, comprising a driving unit for activating left and/or right direction indicators (turning lights) in response to a driving command.

Such direction indicator control devices are generally known. They are also generally referred to as turning light controls and serve to activate the right and/or left turning light of a vehicle, meaning that the light is switched on and off. The activation is normally caused in response to a manually given driving or control command. The driving command is normally given by operating a switch at the steering column assembly.

Beside the mere indication of the direction turning lights are more and more used as a communication means between truckers. Truckers communicate certain information via a certain activation sequence of the turning lights.

### SUMMARY OF THE INVENTION

The object of the present invention is to provide a direction indicator control device which allows to simplify such a communication between truckers.

The object is solved by a direction indicator control device as mentioned above which comprises a transmitting unit for transmitting a start command and a receiving unit comprising a receiver for receiving said start command, a memory storing at least one sequence of driving commands (also referred to as control or activation commands), and a selection and control circuit adapted to select anyone of the sequences of driving commands stored in the memory in response to the start command and to transmit the driving commands of the selected sequence to the driving unit as to activate the direction indicators.

That is in other words that the user has a transmitter allowing to send a start command by pushing a switch or push button switch, and that the receiving unit receives this start command and in response thereto transmits a preset (i.e. set by the user) sequence of driving commands to the driving unit. The result thereof is that the turning lights are switched on and off according to the particular control sequence scheme stored in the memory.

Hence, the user of this direction indicator control device has not to manually operate the switch at the steering column assembly anymore, as to activate the turning lights in the desired sequence. The user has only to push the button on the transmitting unit. With the present invention, the “communication” between truckers is simplified.

In a preferred embodiment, the transmitting unit comprises a circuit adapted to transmit said start command wirelessly.

This measure has the advantage that the transmitting unit may be positioned anywhere within the vehicle. A complex cabling is therefore not required.

Of course, the transmitting unit may alternatively comprise a circuit adapted to transmit said command by wire.

The advantage of such a transmission by wire is that the reliability is increased and the costs are reduced. The transmitting unit could for example be provided in the dashboard of the vehicle so that the cabling is not very complex.

In a preferred embodiment, said memory stores at least two sequences of driving commands, said driving commands of the sequences being different.

This is in other words that the user can select between at least two different sequences of driving commands and hence between two different “communication signs”. Preferably, the transmitting unit comprises respective operating elements for each sequence so that the user can transmit the respective start command for the desired sequence by pushing the respective operating element.

In a preferred embodiment said driving commands stored in said memory are preset by a user. Particularly, said driving commands are preset via said transmitting unit.

That is in other words that the system is programmable by the user. The driving commands associated with a sequence can be input by a user with the above-mentioned measures. The advantage is that the direction indicator control device is very flexible and may be adapted any time to the needs of the user.

In a preferred embodiment, the driving unit is adapted to activate lights (for example the low-beam lights of a vehicle) in response to a driving command.

That is in other words that not only the turning lights but also other light units of the vehicle may be used for this kind of communication. For example, the low-beam lights of the vehicle may be used thereof.

In a preferred embodiment, the transmission rate of the driving commands to the driving unit is adjustable.

That is in other words that the sequence of activating the desired turning lights and other vehicle lights, respectively, may be adjusted in terms of time. A further gain of flexibility and adaptability to the needs of the user is hence achievable.

Further features and advantages can be taken from the following description and the enclosed drawings.

It is to be understood that the features mentioned above and those yet to be explained below can be used not only in the respective combinations indicated, but also in other combinations or in isolation, without leaving the scope of the present invention.

### BRIEF DESCRIPTION OF THE DRAWINGS

An embodiment of the invention is shown in the drawings and will be explained in more detail in the description below with reference to same.

FIG. 1 is a schematic block diagram of a direction indicator control device according to the present invention, and

FIG. 2 is an illustrative dump of the memory in the form of a table.

### DESCRIPTION OF PREFERRED EMBODIMENTS

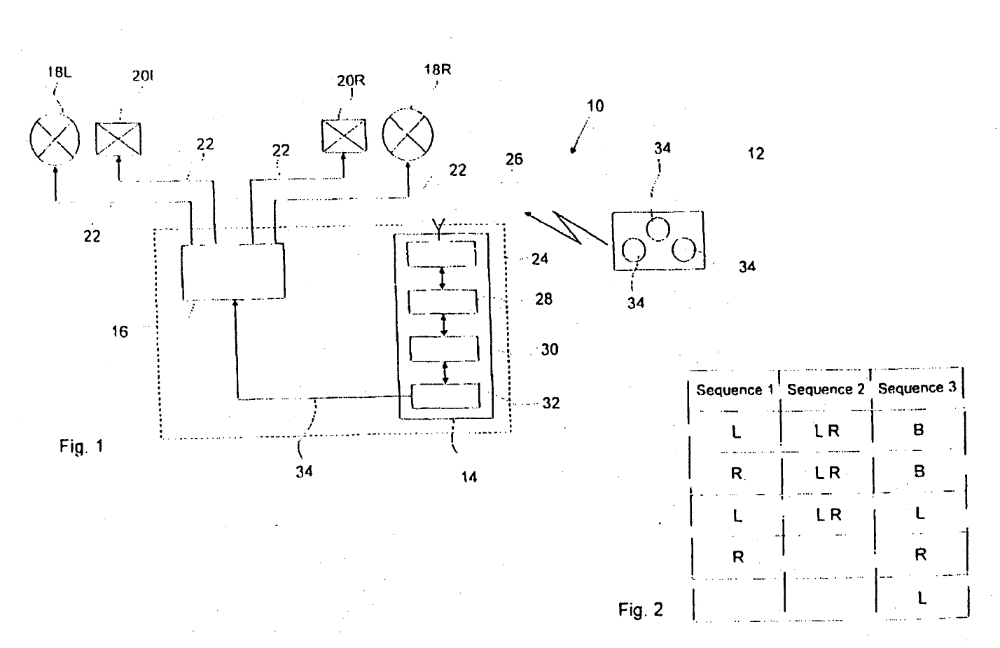

In FIG. 1 a direction indicator control device is shown in form of a block diagram and is indicated with reference numeral 10. This direction indicator control device comprises transmitting unit 12, a receiving unit 14 and a driving unit 16. Both units 14 and 16 may be provided within a housing which is shown in dashed lines.

In FIG. 1, two direction indicators (turning lights) 18L and 18R as well as two low-beam lights 20L and 20R are shown for illustrative purposes. The characters L and R behind the reference numerals refer to left and right. However, it is to be understood that the driving unit may driver further turning lights 18 and low-beam lights, respectively, within a vehicle.

also merely illustrative supply lines 22 between the driving unit 16 and the turning lights 18L, R and low-beam lights 20L, R are shown. These lines 22 indicate that the driving unit 16 applies a voltage to both supply lines of the turning lights and the low-beam lights as to activate them. That means that the driving unit 16 applies the supply voltage of the vehicle to the supply lines of the turning light and the low-beam light, respectively. The switching elements, like relays, etc., coupled with the turning lights and the low-beam lights of the vehicle and required during “normal” operation are hence bypassed.

Of course it would also be possible that the driving unit 16 transmits control commands to the vehicle own switching elements to respectively switch the turning lights and the low-beam lights, respectively. However, this requires more modifications of the electronics within the vehicle.

As it is shown from the above, the driving unit 16 is in the simplest case a series of switches providing a connection between the vehicle is supply voltage and the supply lines of the turning lights and the low-beam lights, respectively.

The receiving unit 14 comprises a receiver 24 which is adapted to receive radio frequency signals via an antenna 26. The receiving unit 14 further comprises a memory 28 as well as a selection and control means 30, all adapted to communicate with each other via respective lines. Finally, a transmission means 32 is provided which transmits respective switching signals to the driving unit 16 via lines 34. It is to be noted that the above-mentioned functional units may be provided in form of electronic integrated circuits. Of course, particular elements of the receiving unit 14 may also be implemented as single components.

In the present embodiment, the transmitting unit 12 comprises three push buttons 34 and respective components for generating radio frequency signals in response to the operation of a push button 34. It is to be understood that the transmitter of the transmitting unit 12 and the receiver 24 of the receiving unit 14 are adapted to each other. They may be provided as off-the-shelf commercially available radio frequency components which transmit in allowed radio frequency bands.

In the memory 26, which is provided as a non-volatile re-writable memory, different sequences of driving commands are stored which may be transmitted to the driving unit 16 and used to cause an activation of a turning light and a low-beam light, respectively. Hence, there are driving commands for turning light left (referenced with L), turning light right (referenced with R) and for low-beam lights left and right (indicated with B). if for example the driving command “L” is transmitted to the driving unit via the transmission means 32, the turning light 18L is activated in response thereto, that is the turning light is switched on and is switched off after a predetermined time period.

Each of the sequences stored in the memory 28 comprises at least one driving command, preferably a plurality of driving commands, which are transmitted by the transmission means 32 to the driving unit 16 in the stored sequence.

In FIG. 2 a dump of the memory 28 is shown merely illustrative. There are three sequences in total, the first sequence 1 comprises the driving commands L, R, L, R, the sequence 2 comprises the commands LR, LR, LR and the sequence 3 comprises the driving commands B, B, L, R, L. The operator of the sequence 1, that is the transmission of the respective driving commands to the driving unit 16 hence causes the activation of the left turning lights 18L, then the right turning light 18R, then the left turning light 18L and finally the right turning light 18R. The driving commands of the sequence 2 cause both turning lights 18L, 18R to be switched on and off simultaneously three times in total.

In addition to the three sequences shown in FIG. 2, it is to be understood that a lot more sequences of driving commands may be stored. Only the size of the memory limits the number and the length of the sequences.

By means of the receiving unit 12, the user may call a stored sequence and may start it. This is achieved by operating one of the push buttons 34 transmitting a respective signal which is received by the receiver 24 and which is evaluated or processed by the selection and control means 30. Particularly, the means 30 selects a sequence associated with the received signal in the memory 28 and forwards stored data to the transmission means 32. These data are then transmitted—as already mentioned—to the driving unit 16.

In the present embodiment, the receiving unit comprises three push buttons in total so that three of the stored sequences may be called via these push buttons easily. Of course, further sequences may be selected by assigning each push button 34 more than one sequence which are selectable by repeated operation of a push button.

In case that the user wants to call the sequence 1, for example, he operates the left push button 34 of the transmitting unit 12, and in case that he wants to call sequence 3, he operates the right push button 34.

The advantage of this driving control is that the user may transmit a predetermined number of driving commands just with a single operation of a push button. In the prior art a respective number of operations of the switch at the steering column assembly for driving the turning lights were necessary.

The sequences stored in the memory 28 may either be preset or may preferably be programmed by the user. This programming is preferably carried out by means of the receiving unit 12 which may be set into a programming mode. In this programming mode each switch button 34 is assigned a predetermined driving command (L, R, B) so that by operating a push button the respectively assigned driving command is stored in the memory 28.

It is to be noted that the programming may be carried out differently without the use of the receiving unit 12. However, it is particularly advantageous if the user may establish and store the sequences by himself or may modify or overwrite them later. As a result the whole system becomes more flexible and user friendly.

What is claimed is:

1. Direction indicator control device for vehicles, particularly trucks, comprising:
a driving unit for activating a left and/or right direction indicator in response to a driving command,
a transmitting unit for transmitting a start command, and
a receiving unit comprising
a receiver for receiving said start command;
a memory storing at least one sequence of driving commands, and
a selection and control circuit adapted to select any one of the sequences of driving commands stored in the memory in response to the start command and to transmit the driving commands of the selected sequence to the driving unit as to activate the direction indicators.

2. The control device of claim 1, wherein said transmitting unit comprises a circuit adapted to transmit said start command wirelessly.

3. The control device of claim 1, wherein said transmitting unit comprises a circuit adapted to transmit said start command by wire.

4. The control device of claim 1, wherein said memory stores at least two sequences of driving commands, said driving commands of the sequences being different.

5. The control device of claim 1, wherein said driving commands stored in said memory are preset by a user.

6. The control device of claim 5, wherein said driving commands are preset via said transmitting unit.

7. The control device of claim 1, wherein said driving unit is adapted to activate lights of a vehicle.

8. The control device of claim 1, wherein said transmitting unit is adapted to transmit at least two different start commands as to select between a respective number of different sequences.

9. The control device of claim 1, wherein the transmission rate of the driving commands to the driving unit is adjustable.
